(19) United States
(12) Patent Application Publication
(10) Pub. No.: US 2010/0123125 A1
(43) Pub. Date: May 20, 2010

(54) ORGANIC THIN FILM TRANSISTOR, METHOD OF MANUFACTURING THE SAME AND DISPLAY DEVICE USING THE SAME

(76) Inventors: Jaeyoon LEE, Seoul (KR); Myoungho Lee, Seoul (KR)

Correspondence Address: MORGAN LEWIS & BOCKIUS LLP, 1111 PENNSYLVANIA AVENUE NW, WASHINGTON, DC, 20004, US

(21) Appl. No.: 12/606,600

(22) Filed: Oct. 27, 2009

(30) Foreign Application Priority Data
Nov. 14, 2008 (KR) 10-2008-0113619

(51) Int. Cl. H01L 51/50; H01L 51/10; H01L 51/40

(52) U.S. Cl. 257/40; 438/158; 257/98; 345/92; 345/80; 257/E51.026

(57) ABSTRACT

An organic thin film transistor, a method of manufacturing the same, and a display device using the same are provided. The organic thin film transistor includes a source and a drain on a substrate, reverse taper-shaped banks that are positioned on the source and the drain to expose a portion of each of the source and the drain, and an organic semiconductor layer between the reverse taper-shaped banks.

This application claims the benefit of Korean Patent Application No. 10-2008-113619 filed on Nov. 14, 2008, the entire contents of which is hereby incorporated by reference.

### BACKGROUND

1. Field

Embodiments relate to an organic thin film transistor, a method of manufacturing the same, and a display device using the same.

2. Description of the Related Art

With the development of information technology, display devices have been widely used as a connection medium between a user and information. Hence, the use of flat panel displays such as a liquid crystal display (LCD), an organic light emitting diode (OLED) display, a plasma display panel (PDP) has been increasing. Out of the flat panel displays, because the liquid crystal displays can achieve a high resolution and can be manufactured as a large-sized display as well as a small-sized display, they have been widely used.

Some of the display devices are driven by a thin film transistor to display an image. The thin film transistor may include a gate, a semiconductor layer, a source, and a drain.

Recently, a method of manufacturing an organic thin film transistor using an inkjet device has been proposed. In the method using the inkjet device, a bank is formed and then an ink including an organic material is injected into the bank.

When the ink starts to be injected into the bank, a height of a center portion of the injected ink is lower than heights of other portions because of a kinetic energy resulting from a inkjet process. However, after the bank contacts the ink, the ink again flows into a central portion of the bank because of hydrophobic properties of the bank. Therefore, the central portion of the bank is thickly formed. Accordingly, in the related art, it is difficult to control a thickness of a channel region of an organic semiconductor layer. Further, it is difficult to perform crystallinity control in the channel region.

### SUMMARY

In one aspect, there is an organic thin film transistor comprising a source and a drain on a substrate, reverse taper-shaped banks that are positioned on the source and the drain to expose a portion of each of the source and the drain, and an organic semiconductor layer between the reverse taper-shaped banks.

In another aspect, there is a method of manufacturing an organic thin film transistor comprising forming a source and a drain on a substrate, forming reverse taper-shaped banks on the source and the drain to expose a portion of each of the source and the drain, and injecting an ink including an organic material between the reverse taper-shaped banks to form an organic semiconductor layer.

In another aspect, there is a display device comprising an organic thin film transistor including a source and a drain on a substrate and reverse taper-shaped banks that are positioned on the source and the drain to expose a portion of each of the source and the drain, and a light emitting unit including a lower electrode connected to one of the source and the drain, an organic emitting layer on the lower electrode, and an upper electrode on an organic emitting layer.

In another aspect, there is a display device comprising an organic thin film transistor including a source and a drain on a first substrate and reverse taper-shaped banks that are positioned on the source and the drain to expose a portion of each of the source and the drain, an electrode unit including a pixel electrode connected to one of the source and the drain and a common electrode receiving a voltage level lower than a voltage level applied to the pixel electrode, a second substrate that is positioned opposite the first substrate to be spaced apart from the first substrate and is attached to the first substrate, and a liquid crystal layer between the first substrate and the second substrate.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 illustrates an exemplary configuration of a bottom gate type organic thin film transistor according to an embodiment;

FIG. 2 illustrates an exemplary configuration of a top gate type organic thin film transistor according to an embodiment;

FIGS. 3 to 6 are cross-sectional views illustrating each stage in a method of manufacturing an organic thin film transistor according to an embodiment;

FIG. 7 illustrates crystallinity and uniformity of an organic semiconductor layer depending on a shape of a bank;

FIG. 8 illustrates an exemplary configuration of an organic light emitting diode (OLED) display according to an embodiment; and

FIG. 9 illustrates an exemplary configuration of a liquid crystal display according to an embodiment.

### DETAILED DESCRIPTION OF PREFERRED EMBODIMENTS

Reference will now be made in detail embodiments of the invention examples of which are illustrated in the accompanying drawings.

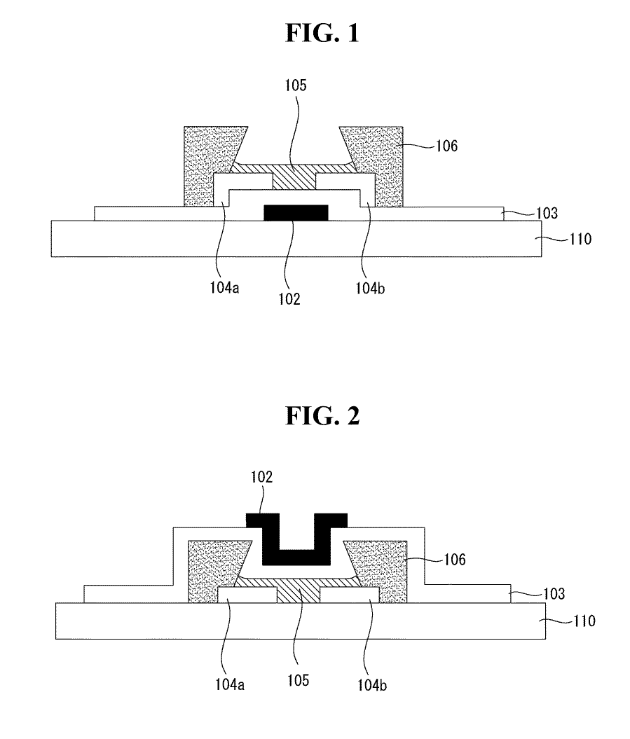

FIG. 1 illustrates an exemplary configuration of a bottom gate type organic thin film transistor according to an embodiment, and FIG. 2 illustrates an exemplary configuration of a top gate type organic thin film transistor according to an embodiment.

As shown in FIG. 1, a bottom gate type organic thin film transistor according to an embodiment includes a gate 102 on a substrate 110, a first insulating layer 103 on the gate 102, a source 104a and a drain 104b on the first insulating layer 103, reverse taper-shaped banks 106 that are positioned on the source 104a and the drain 104b to expose a portion of each of the source 104a and the drain 104b, and an organic semiconductor layer 105 between the reverse taper-shaped banks 106.

As shown in FIG. 2, a top gate type organic thin film transistor according to an embodiment includes a source 104a and a drain 104b on a substrate 110, reverse taper-shaped banks 106 that are positioned on the source 104a and the drain 104b to expose a portion of each of the source 104a and the drain 104b, an organic semiconductor layer 105 between the reverse taper-shaped banks 106, a first insulating layer 103 on the banks 106, and a gate 102 on the first insulating layer 103.

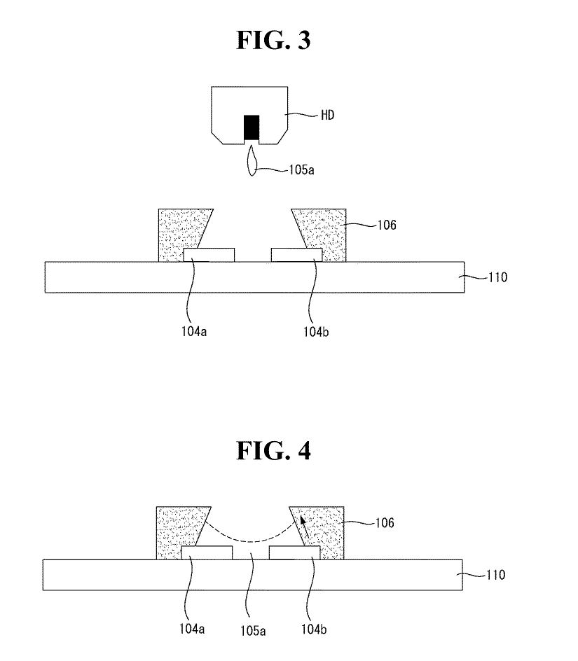

FIGS. 3 to 6 are cross-sectional views illustrating each stage in a method of manufacturing an organic thin film transistor according to an embodiment. More specifically, FIGS. 3 to 6 illustrate a method of manufacturing a top gate type organic thin film transistor.

As shown in FIG. 3, a source 104a and a drain 104b are formed on a substrate 110. The source 104a and the drain 104b may have a single-layered structure or a multi-layered structure.

Next, reverse taper-shaped banks 106 are formed on the source 104a and the drain 104b to expose a portion of each of the source 104a and the drain 104b. In a process for forming the bank 106, the reverse taper-shaped banks 106 have reverse taper surfaces in the exposed portions of the source 104a and the drain 104b and may have other shapes other than the reverse taper shape in non-exposed portions of the source 104a and the drain 104b. The bank 106 may be formed of a hydrophobic material or a non-hydrophobic material. In case the bank 106 is formed of the non-hydrophobic material, an upper surface of the bank 106 may be surface-processed so as to have hydrophobicity. The surface processing is performed using a material obtained by mixing a fluorine gas such as hydrophobic plasma (for example, CF₄, SF₆) with oxygen (O₂) at a predetermined ratio. Other materials may be used. Because plasma processing is not performed on a reverse taper surface of the reverse taper-shaped bank 106 in the surface processing of the bank 106 using the above-described method, only the upper surface of the bank 106 has hydrophobicity and the reverse taper surface of the bank 106 has hydrophilicity. On the other hand, in case the bank 106 is formed of the hydrophobic material, most of hydrophobic groups gather on an upper portion of the bank 106 in a soft bake process because of properties of the hydrophobic material, and a small amount of hydrophobic groups gathers in a lower portion of the reverse taper-shaped bank 106. Therefore, the lower portion of the reverse taper-shaped bank 106 has hydrophilicity.

Next, an ink 105a including an organic material is injected between the banks 106 to form an organic semiconductor layer. The organic material may use pentacene-based material or thiophene-based material. Other materials may be used. An inkjet device may be used to inject the ink 105a. In FIG. 3, HD indicates a head of the inkjet device.

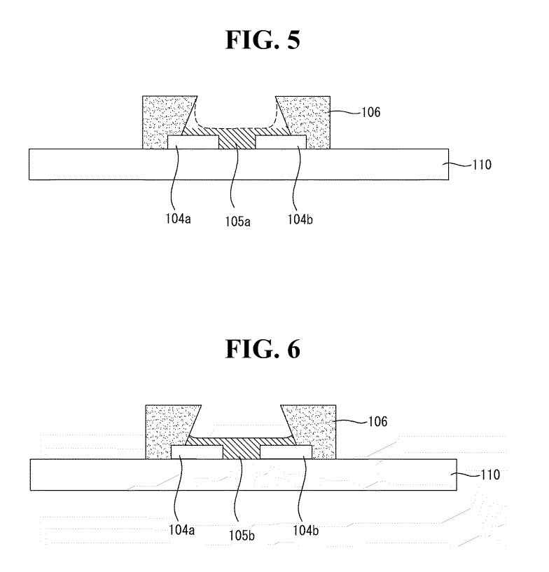

As shown in FIGS. 4 and 5, the ink 105a injected by the inkjet device spreads around the bank 106, and thus the reverse taper surface of the bank 106 has hydrophilicity. Because the reverse taper surface of the bank 106 having hydrophilicity attracts the ink 105a because of its surface energy, an ink injection height of the reverse taper surface of the bank 106 increases through the attraction. Therefore, an ink injection height of a central portion of the bank 106 does not increase. Accordingly, the ink 105a may be uniformly injected into the bank 106.

As shown in FIG. 6, the ink 106 is dried, and then an organic semiconductor layer 105b is formed between the backs 106. A channel region of the organic semiconductor layer 105b hardens in the form of a uniformly thin layer in a uniform direction to have crystallinity.

The bank 106 may be formed so that a thickness of the bank 106 is substantially 2 to 8 times a thickness of the channel region of the organic semiconductor layer 105b. When the thickness of the bank 106 is equal to or greater than 2 times the thickness of the channel region of the organic semiconductor layer 105b, after the injection of the ink 105a, non-uniformity of crystals of the channel region and a reduction in a planarization level of the channel region may be prevented because of the surface energy of the reverse taper surface of the bank 106 having the hydrophilicity. When the thickness of the bank 106 is equal to or less than 8 times the thickness of the channel region of the organic semiconductor layer 105b, after the injection of the ink 105a, a depletion phenomenon of the channel region and a reduction in a performance of the thin film transistor may be prevented because of the surface energy of the reverse taper surface of the bank 106 having the hydrophilicity.

As above described, there is a strong correlation between the thickness of the bank 106 and the thickness of the channel region of the organic semiconductor layer 105b. According to an experiment, when the thickness of the bank 106 was 4 to 7 times the thickness of the channel region of the organic semiconductor layer 105b, the crystal uniformity, the planarization level, and the performance of the thin film transistor were excellent.

In a process for forming the organic semiconductor layer 105b, a formation area of the substrate 110 or the bank 106 may be heated at approximately 40° C. to 80° C. The formation area of the substrate 110 may be heated using a method of heating a stage, as such, or a method of heating a dropping portion of the ink 105a using ultraviolet rays (UV) or infrared rays (IR). Other methods may be used.

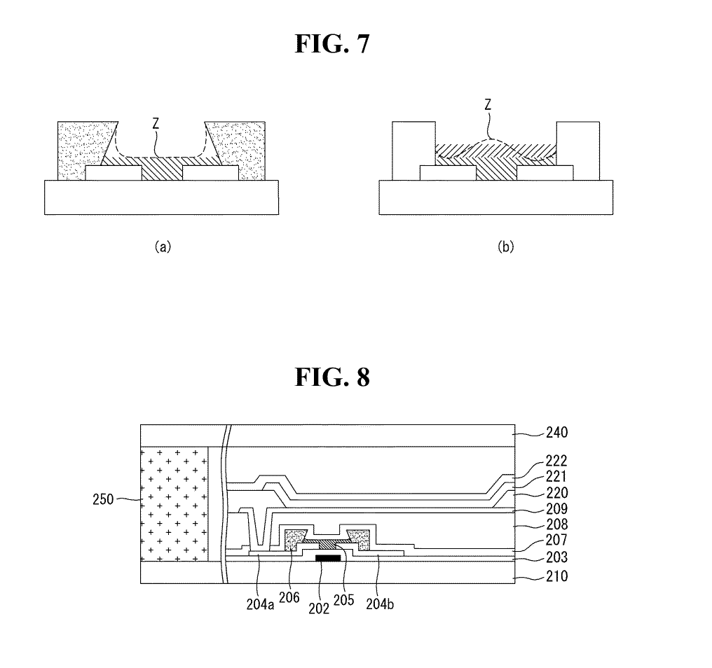

FIG. 7 illustrates crystallinity and uniformity of an organic semiconductor layer depending on a shape of a bank.

In FIG. 7, (a) partially shows an organic thin film transistor according to an embodiment, and (b) partially shows a related art organic thin film transistor.

It can be seen from (a) of FIG. 7 that a channel region Z of the organic thin film transistor according to the embodiment has crystallinity in one direction and is uniformly thin.

On the other hand, it can be seen from (b) of FIG. 7 that a channel region Z of the related art organic thin film transistor has crystallinity in different directions and is nonuniformly thick.

As described above, the organic thin film transistor according to the embodiment may be applied to the OLED display or the liquid crystal display.

FIG. 8 illustrates an exemplary configuration of an OLED display according to an embodiment.

As shown in FIG. 8, the OLED display according to the embodiment may include an organic thin film transistor on a substrate 210 and a light emitting unit that emits light due to a drive of the organic thin film transistor. The OLED display may have a seal substrate 240 for protecting elements on the substrate 210, and the substrate 210 and the seal substrate 240 may be attached to each other using an adhesive 250. The OLED display according to the embodiment will be described in detail below.

A gate 202 may be positioned on the substrate 210. The gate 202 may be formed of one selected from the group consisting of molybdenum (Mo), aluminum (Al), chromium (Cr), gold (Au), titanium (Ti), nickel (Ni), neodymium (Nd) and copper (Cu), or a combination thereof. The gate 202 may have a multi-layered structure formed of Mo, Al, Cr, Au, Ti, Ni, Nd, or Cu, or a combination thereof. For example, the gate 202 may have a double-layered structure including Mo/Al—Nd or Mo/Al.

A first insulating layer 203 may be positioned on the gate 202. The first insulating layer 203 may be formed of silicon oxide (SiO_{X}), silicon nitride (SiN_{X}), or a multi-layered structure or a combination thereof, but is not limited thereto. The first insulating layer 203 may be a gate insulating layer.

A source 204a and a drain 204b may be positioned on the first insulating layer 203. The source 204a and the drain 204b may have a single-layered structure or a multi-layered structure. When the source 204a and the drain 204b have the single-layered structure, the source 204a and the drain 204b may be formed of one selected from the group consisting of Mo, Al, Cr, Au, Ti, Ni, Nd, or Cu, or a combination thereof. When the source 204a and the drain 204b have the multi-layered structure, the source 204a and the drain 204b may have a double-layered structure including Mo/Al—Nd or a triple-layered structure including Mo/Al/Mo or Mo/Al—Nd/Mo.

Next, reverse taper-shaped banks 206 may be formed on the source 204a and the drain 204b to expose a portion of each of the source 204a and the drain 204b. The bank 206 may be formed of a hydrophobic material or a non-hydrophobic material. In case the bank 206 is formed of the non-hydrophobic material, an upper surface of the bank 206 may be surface-processed so as to have hydrophobicity. The surface processing is performed using a material obtained by mixing a fluorine gas such as hydrophobic plasma (for example, CF₄, SF₆) with oxygen (O₂) at a predetermined ratio. Other materials may be used. Because plasma processing is not performed on a reverse taper surface of the reverse taper-shaped bank 206 in the surface processing of the bank 206 using the above-described method, only the upper surface of the bank 206 has hydrophobicity and the reverse taper surface of the bank 206 has hydrophilicity.

An organic semiconductor layer 205 may be formed between the banks 206. The organic semiconductor layer 205 between the banks 206 may be formed using an inkjet device. A channel region of the organic semiconductor layer 205 hardens in the form of a uniformly thin layer in a uniform direction by the method illustrated in FIGS. 3 to 6 to have crystallinity. The bank 206 may be formed so that a thickness of the bank 206 is substantially 2 to 8 times a thickness of the channel region of the organic semiconductor layer 205. When the thickness of the bank 206 is equal to or greater than 2 times the thickness of the channel region of the organic semiconductor layer 205, non-uniformity of crystals of the channel region and a reduction in a planarization level of the channel region may be prevented. When the thickness of the bank 206 is equal to or less than 8 times the thickness of the channel region of the organic semiconductor layer 205, a depletion phenomenon of the channel region and a reduction in a performance of the thin film transistor may be prevented.

A second insulating layer 207 may be positioned on the bank 206 and the organic semiconductor layer 205 to cover the bank 206 and the organic semiconductor layer 205. The second insulating layer 207 may be formed of silicon oxide (SiO_{X}), silicon nitride (SiN_{X}), or a multi-layered structure or a combination thereof. Other materials may be used. The second insulating layer 207 may be a passivation layer.

A third insulating layer 208 may be positioned on the second insulating layer 207 to increase a planarization level. The third insulating layer 208 may be formed of an organic material such as polyimide. Other materials may be used for the third insulating layer 208.

A lower electrode 209 may be positioned on the third insulating layer 208 to be connected to the source 204a or the drain 204b. The lower electrode 209 may be an anode electrode or a cathode electrode. In case the lower electrode 209 is an anode electrode, the lower electrode 209 may be formed of a transparent material such as indium tin oxide (ITO), indium zinc oxide (IZO), indium tin zinc oxide (ITZO), and ZnO-doped Al₂O₃ (AZO). Other materials may be used.

A fourth insulating layer 220 may be positioned on the lower electrode 209 to expose a portion of the lower electrode 209. The fourth insulating layer 220 may be formed of an organic material such as benzocyclobutene (BCB)-based resin, acrylic resin, or polyimide resin. Other materials may be used.

An organic light emitting layer 221 may be positioned on an exposed portion of the lower electrode 209 by the fourth insulating layer 220. The organic light emitting layer 221 may emit one of red, green, and blue light.

An upper electrode 222 may be positioned on the organic light emitting layer 221. The upper electrode 222 may be an anode electrode or a cathode electrode. In case the upper electrode 222 is a cathode electrode, the upper electrode 222 may be formed of an opaque material having a low work function such as Al and Al alloy. Other materials may be used.

Even though FIG. 8 shows the bottom gate type organic thin film transistor and the bottom emission OLED display, the embodiment may be applied to other type thin film transistors and other type OLED displays.

In the OLED display thus formed, a data driver and a scan driver respectively supply a data signal and a scan signal, and then a current applied to the first power supply line VDD flows through the second power supply line VSS. Hence, an image is displayed due to the OLED that emits light.

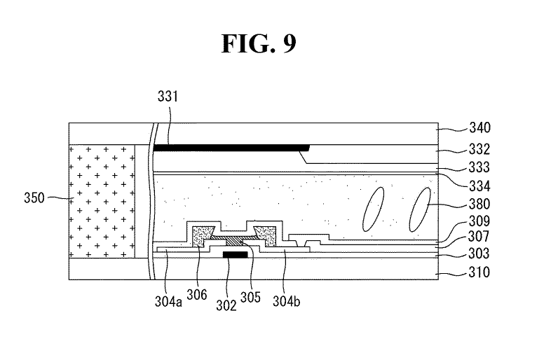

FIG. 9 illustrates an exemplary configuration of a liquid crystal display according to an embodiment.

As shown in FIG. 9, a liquid crystal display according to an embodiment may include an organic thin film transistor on a first substrate 310 and an electrode unit including a pixel electrode connected to a source or a drain of the organic thin film transistor and a common electrode receiving a voltage level lower than a voltage level applied to the pixel electrode. The liquid crystal display may further include a second substrate 340 attached to the first substrate 310 and a liquid crystal layer 380 between the first substrate 310 and the second substrate 340.

A gate 302 may be positioned on the substrate 310. The gate 302 may be formed of one selected from the group consisting of Mo, Al, Cr, Au, Ti, Ni, Nd, and Cu, or a combination thereof. The gate 302 may have a multi-layered structure formed of Mo, Al, Cr, Au, Ti, Ni, Nd, or Cu, or a combination thereof. For example, the gate 302 may have a double-layered structure including Mo/Al—Nd or Mo/Al.

A first insulating layer 303 may be positioned on the gate 302. The first insulating layer 303 may be formed of silicon oxide (SiO_{X}), silicon nitride (SiN_{X}), or a multi-layered structure or a combination thereof, but is not limited thereto. The first insulating layer 303 may be a gate insulating layer.

A source 304a and a drain 304b may be positioned on the first insulating layer 303. The source 304a and the drain 304b may have a single-layered structure or a multi-layered structure. When the source 304a and the drain 304b have the single-layered structure, the source 304a and the drain 304b may be formed of one selected from the group consisting of Mo, Al, Cr, Au, Ti, Ni, Nd, or Cu, or a combination thereof. When the source 304a and the drain 304b have the multi-layered structure, the source 304a and the drain 304b may have a double-layered structure including Mo/Al—Nd or a triple-layered structure including Mo/Al/Mo or Mo/Al—Nd/Mo.

Reverse taper-shaped banks 306 may be formed on the source 304a and the drain 304b to expose a portion of each of the source 304a and the drain 304b. The bank 306 may be formed of a hydrophobic material or a non-hydrophobic material. In case the bank 306 is formed of the non-hydrophobic material, an upper surface of the bank 306 may be surface-processed so as to have hydrophobicity. The surface processing is performed using a material obtained by mixing a fluorine gas such as hydrophobic plasma (for example, CF₄, SF₆) with oxygen (O₂) at a predetermined ratio. Other materials may be used. Because plasma processing is not performed on a reverse taper surface of the reverse taper-shaped bank 306 in the surface processing of the bank 306 using the above-described method, only the upper surface of the bank 306 has hydrophobicity and the reverse taper surface of the bank 306 has hydrophilicity.

An organic semiconductor layer 305 may be formed between the banks 306. The organic semiconductor layer 305 between the banks 306 may be formed using an inkjet device. A channel region of the organic semiconductor layer 305 hardens in the form of a uniformly thin layer in a uniform direction by the method illustrated in FIGS. 3 to 6 to have crystallinity. The bank 306 may be formed so that a thickness of the bank 306 is substantially 2 to 8 times a thickness of the channel region of the organic semiconductor layer 305. When the thickness of the bank 306 is equal to or greater than 2 times the thickness of the channel region of the organic semiconductor layer 305, non-uniformity of crystals of the channel region and a reduction in a planarization level of the channel region may be prevented. When the thickness of the bank 306 is equal to or less than 8 times the thickness of the channel region of the organic semiconductor layer 305, a depletion phenomenon of the channel region and a reduction in a performance of the thin film transistor may be prevented.

A second insulating layer 307 may be positioned on the bank 306 and the organic semiconductor layer 305 to cover the bank 306 and the organic semiconductor layer 305. The second insulating layer 307 may be formed of silicon oxide (SiO_{X}), silicon nitride (SiN_{X}), or a multi-layered structure or a combination thereof. Other materials may be used. The second insulating layer 307 may be a passivation layer.

A pixel electrode 309 may be positioned on the second insulating layer 307 to be connected to the source 304a or the drain 304b. The pixel electrode 309 may be formed of a transparent material such as indium tin oxide (ITO), indium zinc oxide (IZO), indium tin zinc oxide (ITZO), and ZnO-doped Al₂O₃ (AZO). Other materials may be used.

Black matrixes 331 may be positioned on the second substrate 340. The black matrixes 331 may be formed of a photosensitive organic material to which a black pigment is added. The black pigment may use carbon black or titanium oxide. Other materials may be used for the black pigment.

A color filter 332 including red, green and blue filters may be positioned between the black matrixes 331. The color filter 332 may include other color filters in addition to the red, green and blue filters.

An overcoating layer 333 may be positioned on the color filter 332 to cover the black matrixes 331 and the color filter 332. In some cases, however, the overcoating layer 333 may be omitted.

A common electrode 334 receiving a voltage level lower than a voltage level applied to the pixel electrode 309 may be positioned on the overcoating layer 333. The common electrode 334 may be formed of the same material as the pixel electrode 309. Other materials may be used.

Although it is not shown, a spacer for keeping a cell interval may be positioned between the first substrate 310 and the second substrate 340. The spacer may be positioned on the organic thin film transistor on the first substrate 310. Other locations may be used for the spacer. Although it is not shown, liquid crystal alignment layers may be positioned on the first substrate 310 and the second substrate 340. While FIG. 9 shows the common electrode 334 on the overcoating layer 333 on the second substrate 340, the common electrode 334 may be positioned on the first substrate 31 depending on a driving manner of the liquid crystal layer 380.

In the liquid crystal display thus formed, the organic thin film transistor is driven by a data signal and a scan signal respectively supplied by a data driver and a scan driver, light generated by a backlight unit is controlled by the liquid crystal layer 380, and an image is displayed using light generated by the color filter 332.

As described above, the embodiments can improve characteristics and the planarization level of the organic thin film transistor by forming the organic semiconductor layer having a uniform thickness using the inkjet device. Hence, the performance of the organic thin film transistor can be improved. Further, the embodiments can provide large-sized flexible display devices using the organic thin film transistor.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An organic thin film transistor comprising:
a source and a drain on a substrate;
reverse taper-shaped banks that are positioned on the source and the drain to expose a portion of each of the source and the drain; and
an organic semiconductor layer between the reverse taper-shaped banks.

2. The organic thin film transistor of claim 1, wherein a thickness of each of the banks is substantially 2 to 8 times a thickness of a channel region of the organic semiconductor layer.

3. The organic thin film transistor of claim 1, wherein the reverse taper-shaped banks have reverse taper surfaces in the exposed portions of the source and the drain.

4. A method of manufacturing an organic thin film transistor comprising:
forming a source and a drain on a substrate;
forming reverse taper-shaped banks on the source and the drain to expose a portion of each of the source and the drain; and
injecting an ink including an organic material between the reverse taper-shaped banks to form an organic semiconductor layer.

5. The method of claim 4, wherein forming the reverse taper-shaped banks comprises performing a surface processing on upper surfaces of the banks when the banks are formed of a non-hydrophobic material so that the upper surfaces of the banks have hydrophobicity.

6. The method of claim 4, wherein forming the organic semiconductor layer comprises heating a formation area of the substrate or the banks.

7. The method of claim 4, wherein forming the reverse taper-shaped banks comprises allowing a thickness of each of the banks to be substantially 2 to 8 times a thickness of a channel region of the organic semiconductor layer.

8. The method of claim 4, wherein forming the reverse taper-shaped banks comprises allowing the reverse taper-shaped banks to have reverse taper surfaces in the exposed portions of the source and the drain.

9. A display device comprising:
an organic thin film transistor including a source and a drain on a substrate and reverse taper-shaped banks that are positioned on the source and the drain to expose a portion of each of the source and the drain; and
a light emitting unit including a lower electrode connected to one of the source and the drain, an organic emitting layer on the lower electrode, and an upper electrode on an organic emitting layer.

10. The display device of claim 9, wherein a thickness of each of the banks is substantially 2 to 8 times a thickness of a channel region of the organic semiconductor layer.

11. The display device of claim 9, wherein the reverse taper-shaped banks have reverse taper surfaces in the exposed portions of the source and the drain.

12. A display device comprising:
an organic thin film transistor including a source and a drain on a first substrate and reverse taper-shaped banks that are positioned on the source and the drain to expose a portion of each of the source and the drain;
an electrode unit including a pixel electrode connected to one of the source and the drain and a common electrode receiving a voltage level lower than a voltage level applied to the pixel electrode;
a second substrate that is positioned opposite the first substrate to be spaced apart from the first substrate and is attached to the first substrate; and
a liquid crystal layer between the first substrate and the second substrate.

13. The display device of claim 12, wherein a thickness of each of the banks is substantially 2 to 8 times a thickness of a channel region of the organic semiconductor layer.

14. The display device of claim 12, wherein the reverse taper-shaped banks have reverse taper surfaces in the exposed portions of the source and the drain.
